(19) United States
(12) Patent Application Publication
(10) Pub. No.: US 2020/0243470 A1
(43) Pub. Date: Jul. 30, 2020

(54) ELECTRONIC CONTROL DEVICE

(71) Applicant: HITACHI AUTOMOTIVE SYSTEMS, LTD., Hitachinaka-shi, Ibaraki (JP)

(72) Inventors: Masako KATO, Tokyo (JP); Shinya KAWAKITA, Tokyo (JP)

(73) Assignee: HITACHI AUTOMOTIVE SYSTEMS, LTD., Hitachinaka-shi, Ibaraki (JP)

(21) Appl. No.: 16/754,326

(22) PCT Filed: Sep. 11, 2018
(86) PCT No.: PCT/JP2018/033563

§ 371 Date: Apr. 7, 2020

(30) Foreign Application Priority Data
Oct. 10, 2017 (JP) 2017-196587

(51) Int. Cl. H01L 23/00; H01L 23/498; H02K 11/33; B60K 1/00

(52) U.S. Cl. CPC H01L 24/17; H02K 2211/03; H01L 24/16; H01L 23/49838; H01L 24/13; H01L 24/81; H02K 11/33; B60K 1/00; H01L 2224/16227; H01L 2224/13017; H01L 2224/17051; H01L 2224/13113; H01L 2224/13109; H01L 2224/1312; H01L 2924/014; H01L 2924/3511; H01L 2224/81815; H01L 2224/81191; H01L 23/49811

(57) ABSTRACT

A control unit that controls a motor includes a semiconductor device, the semiconductor device includes a semiconductor package including a plurality of first electrodes, a wiring board including a plurality of second electrodes arranged so as to correspond to each of the plurality of first electrodes, and solder joints connecting the plurality of first electrodes and the plurality of second electrodes, and a tip end of a second electrode arranged at an outermost corner of the wiring board is located outside an outer peripheral end of the semiconductor package.

### TECHNICAL FIELD

The present invention relates to an electronic control unit.

### BACKGROUND ART

In recent years, with a miniaturization, a higher density, and a higher functionality of electronic devices, the miniaturization and the higher density of a semiconductor device are also required. Therefore, as the semiconductor device, an area array package semiconductor device such as a Ball Grid Array (BGA) or a Chip Size Package (CSP) is often used.

In the area array package semiconductor device, electrodes and solder balls are formed on a back surface at a certain size, area and pitch. Electrodes of a wiring board are also formed at a certain size, area and pitch so as to correspond to these electrodes and solder balls. Then, the package semiconductor device is mounted on the wiring board and heated to form solder bumps, and corresponding electrodes are joined.

For example, PTL 1 discloses a structure in which in a connection between a BGA package and the wiring board, an end portion located at an outermost side of an array among outermost peripheral electrodes of the wiring board is located at an outer side of the array than an end portion located at an outermost side of an array among outermost peripheral electrodes of the BGA package, and an angle between an electrode surface of the wiring board and a solder bump surface is an acute angle.

### CITATION LIST

### Patent Literature

PTL 1: JP-A-2000-114315

### SUMMARY OF INVENTION

### Technical Problem

The area array package semiconductor device is deformed at a time of temperature load due to a difference in linear expansion coefficient of each component, and a stress is applied to solder bumps on an outermost periphery.

In particular, a load on solder bumps at outermost corners of the BGA package is large. In these solder bumps, crack extension occurs remarkably especially at an interface with electrodes on an upper side of the solder bumps, and a thermal fatigue life is reduced.

Specifically, in the semiconductor device in which an area array package is connected to the wiring board via the solder bumps, the entire semiconductor device is deformed due to a temperature change in a use environment. However, each component has a different amount of warpage due to the difference in linear expansion coefficient, and the crack extension occurs in the solder bumps between the area array package and the wiring board. In particular, the solder bumps at the outermost corners of the area array package are easily broken, the thermal fatigue life is reduced, and a reliability of the semiconductor device is reduced.

PTL 1 mentions that the stress applied to the solder bumps on the outermost periphery during an external impact is reduced. However, the amount of warpage differs due to the difference in the linear expansion coefficient of the component, and no consideration is given to a fact that the difference affects the thermal fatigue life.

An object of the invention is to prevent a thermal fatigue life from being shortened in an electronic control unit including a semiconductor device.

### Solution to Problem

An electronic control unit according to one aspect of the invention includes a control unit that controls a motor. The control unit includes a semiconductor device. The semiconductor device includes a semiconductor package including a plurality of first electrodes, a wiring board including a plurality of second electrodes arranged so as to correspond to each of the plurality of first electrodes, and solder joints connecting the plurality of first electrodes and the plurality of second electrodes, and a tip end of a second electrode arranged at an outermost corner of the wiring board is located outside an outer peripheral end of the semiconductor package.

### Advantageous Effect

According to one aspect of the invention, the thermal fatigue life is prevented from being shortened in the electronic control unit including the semiconductor device.

### BRIEF DESCRIPTION OF DRAWINGS

FIG. 1 is a cross-sectional view of a semiconductor device according to a first embodiment.

FIG. 2 is a plan view of the semiconductor device according to the first embodiment.

FIGS. 3A-3D are cross-sectional views showing manufacturing steps of the semiconductor device according to the first embodiment.

FIG. 4 is a plan view of a semiconductor device according to a second embodiment.

FIG. 5 is a plan view of the semiconductor device according to the second embodiment.

FIG. 6 is a plan view of a semiconductor device according to a third embodiment.

FIG. 7 is a block diagram of an electronic control unit according to a fourth embodiment.

FIG. 8 is a cross-sectional view of a semiconductor device mounted on the electronic control unit according to the fourth embodiment.

### DESCRIPTION OF EMBODIMENTS

Electrodes and solder balls of an area array package semiconductor device (semiconductor package) are formed in advance by a package manufacturer and a composition of a solder ball is generally Sn-3.0Ag-0.5Cu.

By reducing a size and a pitch of solder bumps, a large number of solder bumps can be arranged within a certain area, which is advantageous for miniaturization and high density. Further, since a wiring length is smaller than that of a structure connected via leads, it is advantageous for high-speed transmission and high performance can be achieved.

In a BGA package of the area array package semiconductor device, a Si chip as a semiconductor element is connected to an interposer by, for example, a wire. The electrodes and the solder balls are formed on a back surface of the interposer and are molded thereon with a resin. The BGA package is connected to a wiring board via solder bumps. However, due to a difference in linear expansion coefficient of each component, the BGA package is deformed at a time of temperature load, and a stress is applied to solder bumps on an outermost periphery of the BGA package.

In particular, a load on solder bumps at outermost corners of the BGA package is large. In these solder bumps, crack extension occurs remarkably especially at an interface with electrodes on an upper side of the solder bumps, which causes a reduction in a thermal fatigue life.

In the following embodiments, in a semiconductor device in which an area array package is connected to the wiring board via solder bumps, the stress applied to the solder bumps at the outermost corners is reduced to prevent the reduction in the thermal fatigue life.

Hereinafter, the embodiments will be described with reference to the drawings.

### First Embodiment

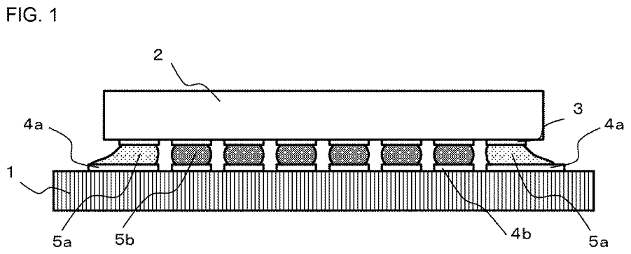

A semiconductor device according to the first embodiment will be described with reference to FIGS. 1 to 3.

As shown in FIG. 1, the semiconductor device includes a wiring board 1 and a semiconductor package (area array package) 2. The wiring board 1 includes a plurality of electrodes 4 on an upper surface. The semiconductor package 2 includes a plurality of electrodes 3 on a lower surface. The semiconductor package 2 is mounted facing the wiring board 1 via solder joints (bumps) 5 that connect the plurality of electrodes 4 to the plurality of electrodes 3.

Among the electrodes 4 formed on the upper surface of the wiring board 1, electrodes 4b at positions other than outermost corners are uniformly formed so as to face the electrodes 3 provided on the lower surface of the semiconductor package 2. Solder joints 5b at positions other than the outermost corners have a drum-shaped bump shape. Solder joints 5a arranged at the outermost corners have a fillet shape extending outward from an outer peripheral end of the semiconductor package 2.

Tip ends of four electrodes 4a at the outermost corners are located outside the outer peripheral end of the semiconductor package 2. Therefore, tip ends of the solder joints 5a at the outermost corners are also located outside the outer peripheral end of the semiconductor package 2.

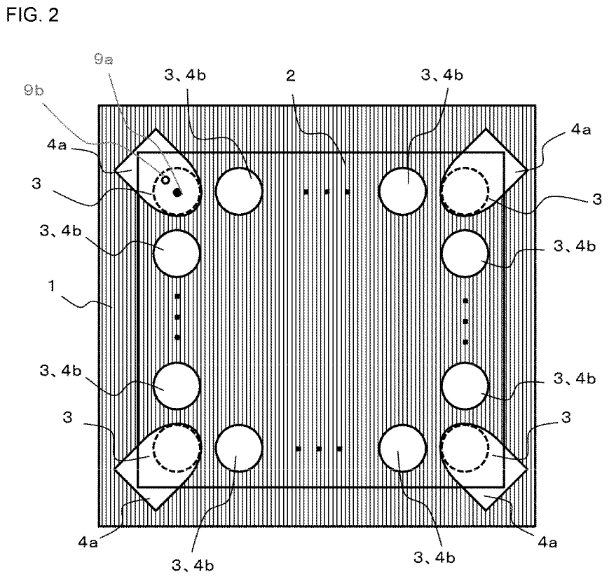

As shown in FIG. 2, the semiconductor package 2 is mounted on the wiring board 1. The electrodes 4b on the wiring board at positions other than the outermost corners are arranged in a circular shape so as to correspond to the electrodes 3 provided on the lower surface of the semiconductor package 2. A size of the electrodes 4b may be the same as the electrodes 3 or may not be the same from a viewpoint of production, and may be appropriately designed.

As shown in FIG. 2, a shape of the electrodes 4a on the wiring board 1 at the outermost corners is set such that a shape of ends inside the semiconductor package 2 is circular and a shape of ends outside the semiconductor package 2 has corners. However, the shape is not limited to this shape as long as the tip ends of the electrodes 4a on the wiring board 1 at the outermost corners are outside an outer periphery of the semiconductor package 2, and the ends outside the semiconductor package 2 may also be circular, and the shape of the electrodes 4a may be elliptical.

In this way, in the semiconductor device according to the first embodiment, the tip ends of the electrodes 4a arranged at the outermost corners of the wiring board 1 are located outside the outer peripheral end of the semiconductor package 2. Further, the tip ends of the solder joints 5a arranged at the outermost corners of the wiring board 1 are also located outside the outer periphery end of the semiconductor package 2.

An area of the electrodes 4a arranged at the outermost corners of the wiring board 1 is larger than an area of the electrodes 3 arranged at outermost corners of the semiconductor package 2. Further, the area of the electrodes 4a arranged at the outermost corners of the wiring board 1 is larger than an area of the electrodes 4b arranged at positions other than the outermost corners of the wiring board 1.

As shown in FIG. 2, centers 9b of the electrodes 4a arranged at the outermost corners of the wiring board 1 are displaced outward from a center of the semiconductor package 2 with respect to centers 9a of the electrodes 3 arranged at the outermost corners of the semiconductor package 2.

A shape of the solder joints 5a arranged at the outermost corners of the wiring board 1 is different from a shape of the solder joints 5b arranged at positions other than the outermost corners of the wiring board 1. Specifically, the solder joints 5a arranged at the outermost corners of the wiring board 1 have the fillet shape extending outward from the outer peripheral end of the semiconductor package 2. The solder joints 5b arranged at positions other than the outermost corners of the wiring board 1 have a drum-shaped shape.

As shown in FIG. 2, the electrodes 4a arranged at the outermost corners of the wiring board 1 are arranged on diagonal lines of the outermost corners.

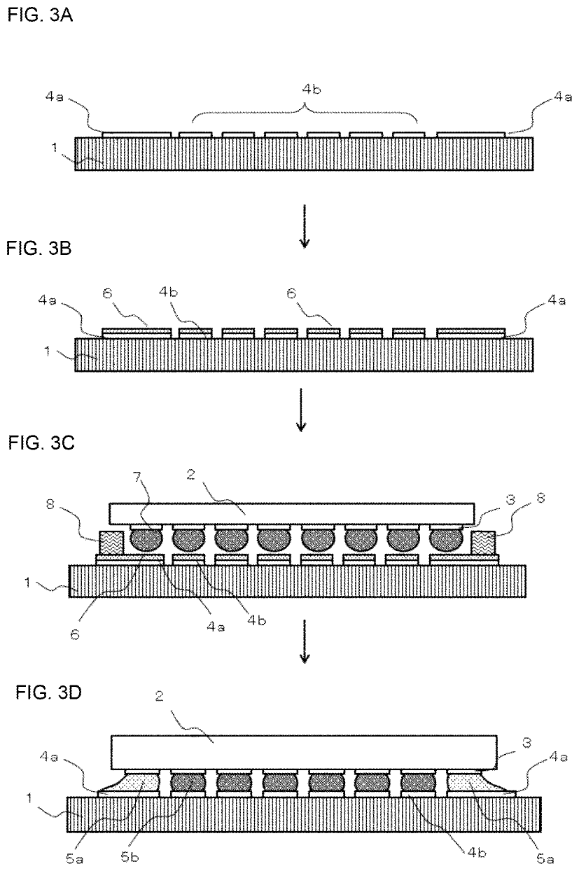

Next, a manufacturing step of the semiconductor device according to the first embodiment will be described with reference to FIG. 3.

First, the plurality of electrodes 4 are formed on the wiring board 1 (see FIG. 3A). Here, the wiring board 1 includes the plurality of electrodes 4 on the upper surface thereof. In the electrodes 4, the electrodes 4a at the outermost corners have an area different from that of the electrodes 4b at positions other than the outermost corners, and the area of the electrodes 4a is larger than the area of the electrodes 4b.

Next, receiving solders 6 are formed on the electrodes 4 on the wiring board 1 (see FIG. 3B). At this time, the receiving solders 6 may be formed by printing or may be applied by a dispenser, and a forming method thereof is not limited thereto. A composition of the receiving solders 6 may be the same as or different from that of solder balls 7 formed in advance on the semiconductor package 2, which is determined comprehensively from viewpoints of jointing, productivity and reliability of electronic components other than the semiconductor package 2 mounted on the wiring board 1.

The semiconductor package 2 is mounted on locations where the receiving solders 6 are formed using a mounting machine (not shown). Then, metal sheets 8 containing any one or a plurality of elements of Bi, In, and Sb are mounted on the electrodes 4a on the wiring board 1 corresponding to the outermost corners of the semiconductor package 2 (see FIG. 3C). At this time, it is desirable from the viewpoint of productivity that the metal sheets 8 also have a chip solder shape that can be mounted on a reel by the mounting machine.

A volume of the metal sheets 8 mounted on the electrodes 4a is calculated from a volume of the solder balls 7 provided on the semiconductor package 2 and the area of the electrodes 4a. It should be noted that the semiconductor package 2 may be mounted after mounting the metal sheets 8 and a mounting order is determined as appropriate.

Next, the semiconductor package 2 and the wiring board 1 on which the metal sheets 8 are mounted are heated by using a reflow furnace (not shown) so that the solder balls 7, the receiving solders 6 and the metal sheets 8 are melted. Thereafter, the semiconductor package 2 and the wiring board 1 are joined by cooling (see FIG. 3D) At this time, the solder joints 5a at the outermost corners of the semiconductor package 2 and the solder joints 5b at positions other than the outermost corners have different metal compositions at the solder joints. Specifically, a concentration of at least one element of Bi, In, and Sb is higher in the solder joints 5a at the outermost corners than in the solder joints 5b. Bi, In, and Sb are elements that improve the thermal fatigue life. The solder joints 5a at the outermost corners of the semiconductor package 2 are different from the solder joints 5b in composition and can be easily changed to a long-life composition. In this way, the semiconductor device shown in FIG. 1 is completed.

In the first embodiment, by melting the metal sheets 8 containing any one or a plurality of elements of Bi, In, and Sb, the one or plurality of metals of Bi, In, and Sb diffuse only into the solder joints 5a at the outermost corners of the semiconductor package 2 whose main composition is SnAgCu. Accordingly, the thermal fatigue life can be extended.

Further, in the first embodiment, by melting the metal sheets 8, a volume of the solder joints 5a at the outermost corners can be easily increased. Accordingly, the solder joints 5a at the outermost corners have the fillet shape and accordingly a manner in which the stress is applied is changed and crack propagation can be prevented. As a result, the stress of the solder joints 5a at the outermost corners of the semiconductor package 2 is reduced, and the reliability of mounting the semiconductor package 2 can be improved.

Further, in the first embodiment, a solder composition of the solder joints 5a at the outermost corners can be changed without changing a solder composition of the solder balls 7 itself of the semiconductor package 2. As a result, a commercially available semiconductor package 2 can be used and accordingly a manufacturing cost can be reduced.

Here, a thermal stress analysis is performed on two patterns of a model A in which a composition of the solder joints 5 is generally Sn-3Ag-0.5Cu and a model B in which a composition of the solder joints 5a is Sn-3Ag-3Bi-3In and the composition of the solder joints 5b is Sn-3Ag-0.5Cu.

In the model A, in a structure in which the areas of the electrodes 4a and 4b formed on the wiring board 1 are the same and the solder joints 5a at the outermost corners of the semiconductor package 2 and the solder joints 5b at positions other than the outermost corners have the same bump shape, the composition of the solder joints 5 is generally Sn-3Ag-0.5Cu. On the other hand, in the model B, in a structure in which the tip ends of the electrodes 4a are located outside the outer peripheral end of the semiconductor package 2 and the solder joints 5a at the outermost corners have the fillet shape, the composition of the solder joints 5a is Sn-3Ag-3Bi-3In and the composition of the solder joints 5b is Sn-3Ag-0.5Cu. The model A and the model B are all the same except for a size of the electrodes 4a and the shape and the composition of the solder joints 5a at the outermost corners.

In an analysis result obtained by applying a thermal load simulating a temperature cycle test in which −40° C. and 125° C. are repeated to the model A and the model B, the thermal fatigue life of the solder joints 5a at the outermost corners in the model B is 1.9 times the thermal fatigue life of the solder joints 5a at the outermost corners in the model A. From the result of the thermal stress analysis, it can be seen that in the first embodiment, the thermal fatigue life is improved.

### Second Embodiment

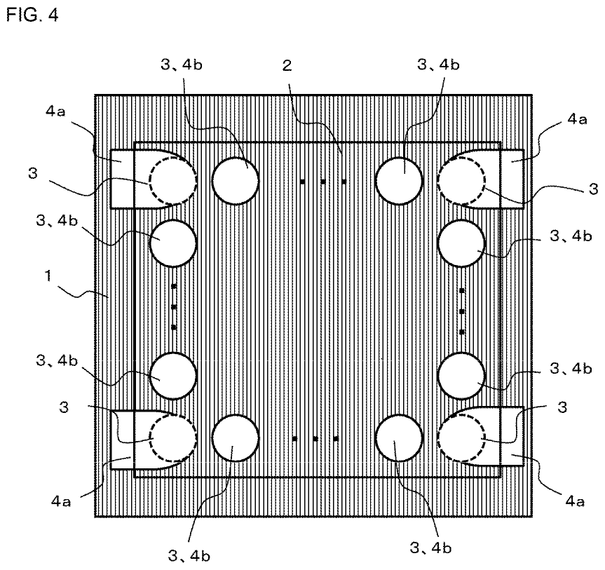

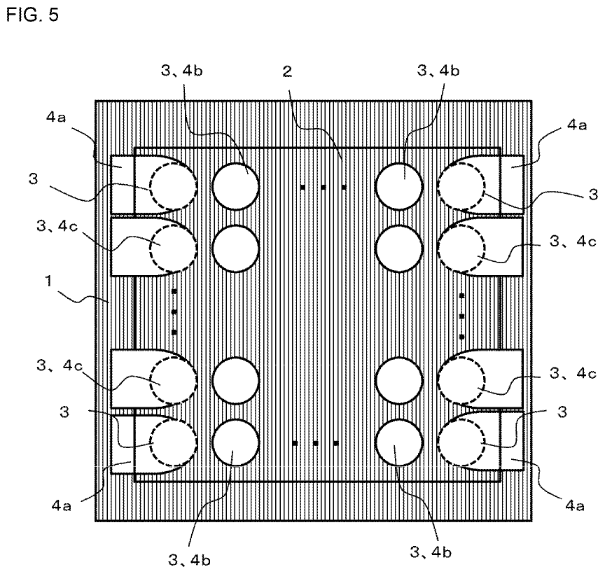

A semiconductor device according to the second embodiment will be described with reference to FIGS. 4 and 5.

In the semiconductor device according to the first embodiment shown in FIG. 2, the electrodes 4a of the wiring board 1 corresponding to the outermost corners of the semiconductor package 2 are arranged on the diagonal lines of the corners. In contrast, in the semiconductor device according to the second embodiment shown in FIG. 4, the electrodes 4a of the wiring board 1 corresponding to outermost corners of the semiconductor package 2 are extended to vertical extensions of opposite sides of the semiconductor package 2. In this case, the solder joints 5a at the outermost corners have a fillet shape having a longer side in a vertical direction of the opposite sides of the semiconductor package 2.

Further, as shown in FIG. 5, in addition to the electrodes 4a at the outermost corners, outer ends of electrodes 4c on an outermost periphery of the opposite sides of the semiconductor package 2 are outside an outer periphery of the semiconductor package 2, and solder joints on the outermost periphery of the opposite sides of the semiconductor package 2 is formed into the fillet shape.

In FIGS. 4 and 5, a composition of the solder joints 5a on the outermost periphery of the opposite sides of the semiconductor package 2 having the fillet shape has a higher concentration of at least one element of Bi, In, and Sb than that of the solder joints 5b.

Other configurations are the same as the semiconductor device according to the first embodiment and a description thereof will be omitted.

### Third Embodiment

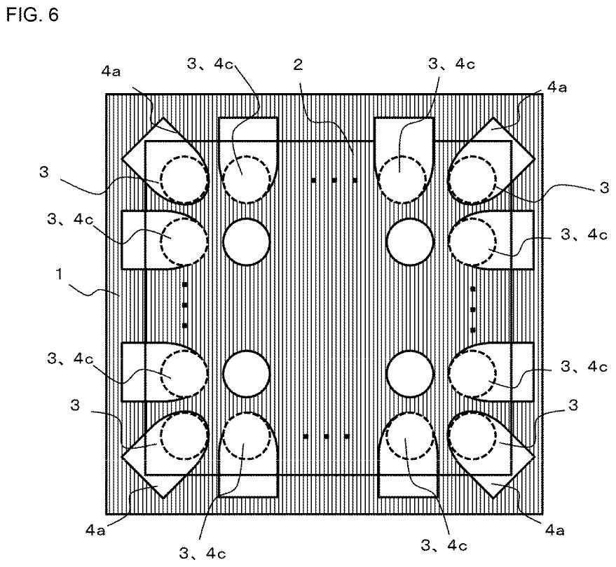

A semiconductor device according to the third embodiment will be described with reference to FIG. 6.

As shown in FIG. 6, in the semiconductor device according to the third embodiment, the electrodes 4a of the wiring board 1 corresponding to outermost corners of the semiconductor package 2 have outer ends thereof on diagonal lines of corners, and the electrodes 4c on an outermost periphery of each of opposite sides of the semiconductor package 2 are extended to an vertical extension of each of the opposite sides of the semiconductor package 2.

In this case, the solder joints 5a at the outermost corners have a fillet shape having a longer side in a diagonal direction of the corners, and the other solder joints on the outermost periphery have a fillet shape having a longer side in a vertical direction of each of the opposite sides of the semiconductor package 2.

The solder joints 5a at the outermost corners may not have the fillet shape having the longer side in the diagonal direction of the corners, and the fillet shape may have the longer side in the vertical direction of any one of the opposite sides of the semiconductor package 2.

In FIG. 6, a composition of the solder joints 5a on the outermost periphery of the semiconductor package 2 having the fillet shape has a higher concentration of at least one element of Bi, In, and Sb than that of the solder joints 5b.

The other configurations are the same as the semiconductor device according to the first embodiment and the description thereof will be omitted.

### Fourth Embodiment

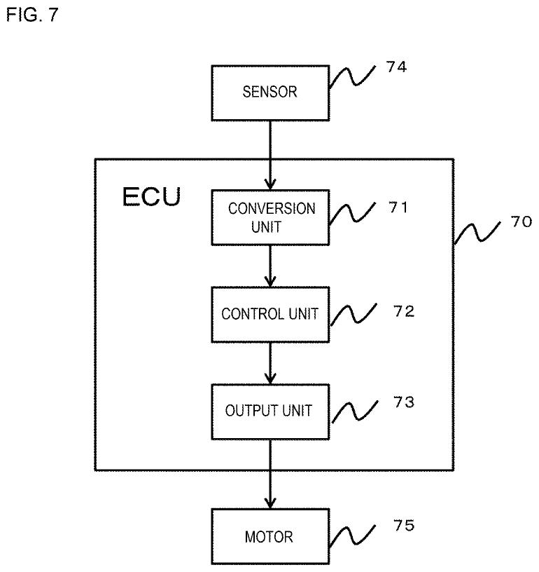

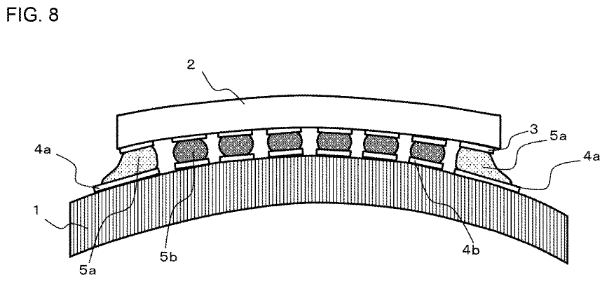

An electronic control unit including the semiconductor device according to the first embodiment will be described with reference to FIGS. 7 and 8.

From a viewpoint of ensuring a cabin space, an installation environment of in-vehicle electronic device is changed from a cabin to an engine room, and resistance in a higher temperature environment is required. From an extension of a vehicle life, there is also a demand for a longer life in the electronic device.

An electronic control unit according to the fourth embodiment will be described with reference to FIG. 7.

As shown in FIG. 7, an electronic control unit (ECU) 70 includes a conversion unit 71, a control unit 72, and an output unit 73, and has a function of transmitting a signal from a sensor unit 74 to a motor unit 75. The semiconductor device according to the first embodiment is mounted on the control unit 72 of the electronic control unit 70.

Here, an engine control unit (ECU) is a microcontroller (microcomputer) that comprehensively controls operation of an engine when the operation is controlled using an electric auxiliary device.

The electronic control unit 70 for in-vehicle use is exposed to an environmental temperature and repeats between a high temperature environment and a low temperature environment. Even in the cabin, a temperature can reach nearly 50° C. when the engine is stopped, and it is exposed to below freezing in a cold region. In the electronic control unit 70 installed in the engine room, a maximum environmental temperature is 100° C. or higher.

FIG. 8 describes a state when the semiconductor device according to the first embodiment mounted on the electronic control unit 70 is placed in an environment where high and low temperatures are repeated.

The wiring board 1 mainly using an organic board and the semiconductor package 2 mounted on the wiring board 1 have different linear expansion coefficients, respectively. Therefore, in the environment where the high and low temperatures are repeated, the wiring board 1 and the semiconductor package 2 have different amounts of warpage, respectively, and a large load is applied to the solder joints 5a at the outermost corners of the semiconductor package 2. Therefore, a large connection length of the solder joints 5a at the outermost corners is effective for the thermal fatigue life up to the crack propagation and a fracture.

### REFERENCE SIGN LIST

1 wiring board

2 semiconductor package

3 electrode

4a electrode at outermost corner

4b electrode at position other than outermost corner

5a solder joint at outermost corner

5b solder joint at position other than outermost corner

70 electronic control unit

71 conversion unit

72 control unit

73 output unit

74 sensor unit

75 motor unit

1. An electronic control unit comprising a control unit that controls a motor, wherein
the control unit includes a semiconductor device,
the semiconductor device includes:
a semiconductor package including a plurality of first electrodes;
a wiring board including a plurality of second electrodes arranged so as to correspond to each of the plurality of first electrodes; and
solder joints connecting the plurality of first electrodes and the plurality of second electrodes, and
a tip end of a second electrode arranged at an outermost corner of the wiring board is located outside an outer peripheral end of the semiconductor package.

2. The electronic control unit according to claim 1, wherein a tip end of a solder joint arranged at the outermost corner of the wiring board is located outside the outer peripheral end of the semiconductor package.

3. The electronic control unit according to claim 2, wherein an area of the second electrode arranged at the outermost corner of the wiring board is larger than an area of a first electrode arranged at an outermost corner of the semiconductor package.

4. The electronic control unit according to claim 3, wherein the area of the second electrode arranged at the outermost corner of the wiring board is larger than an area of a second electrode arranged at a position other than the outermost corner of the wiring board.

5. The electronic control unit according to claim 4, wherein a center of the second electrode arranged at the outermost corner of the wiring board is displaced outward from a center of the semiconductor package with respect to a center of the first electrode arranged at the outermost corner of the semiconductor package.

6. The electronic control unit according to claim 1, wherein a shape of a solder joint arranged at the outermost corner of the wiring board is different from a shape of a solder joint arranged at a position other than the outermost corner of the wiring board.

7. The electronic control unit according to claim 6, wherein the solder joint arranged at the outermost corner of the wiring board has a fillet shape extending outward from the outer peripheral end of the semiconductor package.

8. The electronic control unit according to claim 1, wherein the second electrode arranged at the outermost corner of the wiring board is arranged on a diagonal line of the outermost corner.

9. The electronic control unit according to claim 1, wherein the second electrode arranged at the outermost corner of the wiring board is extended to a vertical extension of opposite sides of the semiconductor package.

10. The electronic control unit according to claim 1, wherein
a composition of a solder joint arranged at the outermost corner of the wiring board is different from a composition of a solder joint arranged at a position other than the outermost corner of the wiring board,
the solder joint arranged at the outermost corner of the wiring board includes at least one element of Bi, In, and Sb, and
a concentration of the at least one element in the solder joint arranged at the outermost corner is higher than a concentration of at least one element of Bi, In, and Sb included in the solder joint arranged at a position other than the outermost corner of the wiring board.

11. The electronic control unit according to claim 1, wherein the semiconductor device of the control unit is mounted on an in-vehicle electronic device.

12. The electronic control unit according to claim 11, wherein
the wiring board and the semiconductor package have different linear expansion coefficients, respectively,
in the in-vehicle electronic device, an amount of warpage of the wiring board and an amount of warpage of the semiconductor package in an environment where high and low temperatures are repeated are different, respectively, and
a load applied to a solder joint arranged at the outermost corner of the wiring board is greater than a load applied to a solder joint arranged at a position other than the outermost corner of the wiring board.
